(19) United States
(12) Patent Application Publication
(10) Pub. No.: US 2026/0028222 A1
(43) Pub. Date: Jan. 29, 2026

(54) MEMS DEVICE

(71) Applicant: ROHM CO., LTD., Kyoto (JP)

(72) Inventors: Martin Wilfried HELLER, Kyoto (JP); Toma FUJITA, Kyoto (JP); Daisuke KAMINISHI, Kyoto (JP)

(73) Assignee: ROHM CO., LTD., Kyoto (JP)

(21) Appl. No.: 19/272,139

(22) Filed: Jul. 17, 2025

(30) Foreign Application Priority Data
Jul. 24, 2024 (JP) 2024-118690

(51) Int. Cl. B81B 3/00; B81C 1/00

(52) U.S. Cl. CPC B81B 3/0081; B81C 1/0069; B81B 2201/0271; B81B 2203/033; B81B 2203/04; B81C 2201/013; B81C 2201/0147; B81C 2201/0197

(57) ABSTRACT

A MEMS device includes a substrate having a front surface and a rear surface, a recess formed in the front surface of the substrate, and a movable electrode and a fixed electrode connected to the substrate and disposed in such a manner as to face each other in the air above the recess. The movable electrode includes an embedded oxide layer embedded in a trench formed in the movable layer. A manufacturing method of a MEMS device includes forming a trench by etching the front surface of the substrate, and forming the embedded oxide layer in the trench by oxidating side surfaces and bottom surface of the trench.

### CROSS REFERENCE TO RELATED APPLICATION

This application is based upon and claims the benefit of priority of the prior Japanese Patent Application No. 2024-118690, filed on Jul. 24, 2024, the entire contents of which are incorporated herein by reference.

### TECHNICAL FIELD

The present invention relates to a MEMS (Micro-Electro-Mechanical System) device, particularly to a MEMS resonator.

### BACKGROUND ART

In MEMS devices using single crystal silicon, such as resonators and acceleration sensors, characteristic parameters of the silicon material (such as temperature coefficient of frequency and Young's modulus) change with temperature. This causes a problem in that the characteristics of the MEMS device also change depending on the temperature.

To address this problem, Japanese Patent Application Laid-open Publication No. 2024-39416 proposes a method of suppressing the temperature dependency of the characteristic parameters by adjusting the type and concentration of dopants added to single crystal silicon to change the electronic band structure of silicon.

### BRIEF DESCRIPTION OF THE DRAWINGS

FIG. 1 is a plan view of a MEMS device according to Embodiment 1 of the present invention.

FIG. 2 is a cross-sectional view of the MEMS device of FIG. 1 viewed from the II-II direction.

FIG. 3A is a cross-sectional view illustrating a manufacturing process of the MEMS device according to Embodiment 1 of the present invention.

FIG. 3B is a cross-sectional view illustrating a manufacturing process of the MEMS device according to Embodiment 1 of the present invention.

FIG. 3C is a cross-sectional view illustrating a manufacturing process of the MEMS device according to Embodiment 1 of the present invention.

FIG. 3D is a cross-sectional view illustrating a manufacturing process of the MEMS device according to Embodiment 1 of the present invention.

FIG. 3E is a cross-sectional view illustrating a manufacturing process of the MEMS device according to Embodiment 1 of the present invention.

FIG. 3F is a cross-sectional view illustrating a manufacturing process of the MEMS device according to Embodiment 1 of the present invention.

FIG. 4 is a plan view of a MEMS device according to Embodiment 2 of the present invention.

FIG. 5 is a cross-sectional view of the MEMS device of FIG. 4 viewed from the V-V direction.

FIGS. 6A, 6B and 6C are schematic views of a manufacturing process of the MEMS device according to Embodiment 2 of the present invention.

FIG. 7 is a plan view of a MEMS device according to Embodiment 3 of the present invention.

FIGS. 8A, 8B and 8C are cross-sectional views of the MEMS device of FIG. 7 viewed from the VIII-VIII direction.

FIGS. 9A, 9B and 9C are cross-sectional views of another MEMS device according to Embodiment 3 of the present invention.

### DETAILED DESCRIPTION OF EMBODIMENTS

### Embodiment 1

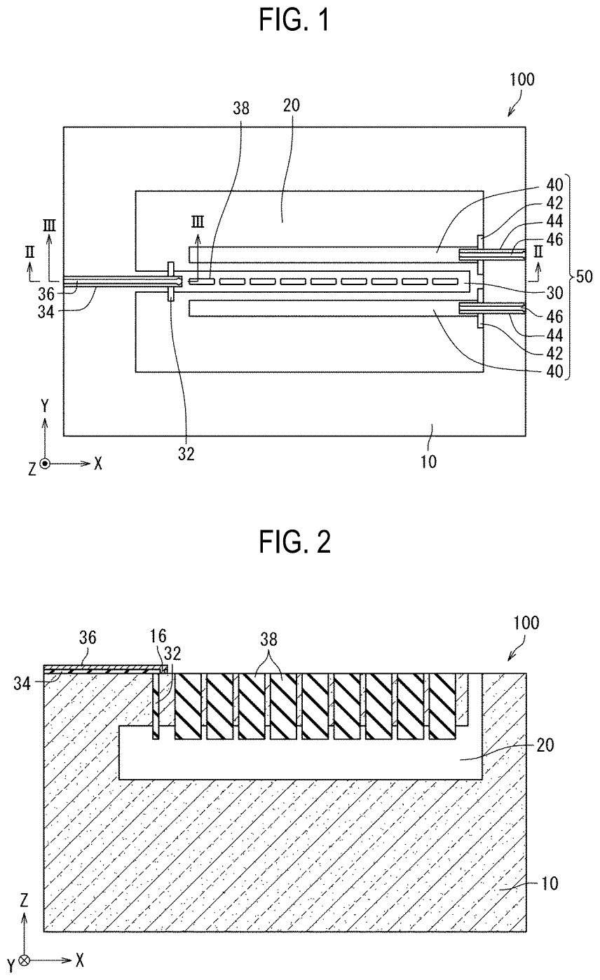

FIG. 1 is a plan view of a MEMS device according to Embodiment 1 of the present invention. The entire device is denoted with 100. FIG. 2 is a cross-sectional view of the MEMS device of FIG. 1 viewed from the II-II direction. Below, a resonator will be explained as an example of the MEMS device 100.

As illustrated in FIGS. 1 and 2, the MEMS device 100 includes a substrate 10 made of single crystal silicon, for example. The substrate 10 has a recess 20 formed therein, and on the recess 20, a vibrator 30 and electrodes 40 arranged to sandwich the vibrator 30 are disposed. The vibrator 30 and the electrodes 40 are arranged in parallel and supported in the air above the recess 20.

The vibrator 30 is formed by etching the substrate 10 made of single crystal silicon, and is insulated from the substrate 10 by an isolation joint (IJ) 32 made of silicon oxide. Furthermore, a passivation film 34 made of silicon oxide, for example, is disposed in such a manner as to straddle the IJ 32, and a wiring layer 36 made of AlCu, for example, is provided thereon. The vibrator 30 is electrically connected to a pad electrode (not shown) and the like by the wiring layer 36.

Similar to the vibrator 30, the electrodes 40 are also formed by etching the substrate 10 made of single crystal silicon, and are insulated from the substrate 10 by an isolation joint (IJ) 42. Furthermore, a passivation film 44 is disposed in such a manner as to straddle the IJ 42, and a wiring layer 46 is provided thereon. The electrodes 40 are electrically connected to a pad electrode (not shown) and the like by the wiring layer 46.

In the vibrator 30, a plurality of silicon oxide layers 38 are embedded in the vertical direction (z-axis direction). In this embodiment, the silicon oxide layers 38 are configured such that the bottom thereof protrudes from the vibrator 30, but they may be embedded such that the bottom thereof does not protrude from the vibrator 30.

In the MEMS device 100 such as a resonator, applying an AC voltage to the vibrator 30 causes the vibrator 30 to resonate, and applying a DC voltage to the electrodes 40 changes the capacitance between the vibrator 30 and the electrodes 40, thereby converting the mechanical vibration of the vibrator 30 into an electrical signal.

In the MEMS device 100 according to Embodiment 1 of the present invention, the temperature-dependent deformation of the vibrator 30, which has a significant effect on the device characteristics, is offset and prevented or reduced by forming the silicon oxide layers 38 having a temperature dependency (such as Young's modulus) opposite to that of silicon, rather than by adding a dopant.

In particular, since the MEMS vibrator 30 made of single crystal silicon has a relatively large frequency fluctuation due to temperature of 20 to 30 ppm/° C., the frequency fluctuation can be effectively reduced or prevented by forming the silicon oxide layers 38.

Here, the linear temperature coefficient of frequency (TCf) will be used as an example of device characteristics that change with temperature.

The temperature coefficient of frequency of the vibrator 30 made of a composite material such as silicon and silicon dioxide, for example, is a sum of the temperature coefficients of frequency of the silicon portion (main body) and the silicon dioxide portion (silicon oxide layers 38) of the vibrator 30. That is, the temperature coefficient of frequency (TCf₁) of the vibrator 30 is expressed by the following formula (1):

$${TCf}_{1} = \frac{{( {TCf}_{1} )}_{{SiO}_{2}} + {r ( {TCf}_{1} )}_{Si}}{1 + r} \qquad Formula ( 1 )$$

where (TCf₁)_{SiO2} is the temperature coefficient of frequency of amorphous silicon oxide constituting the silicon oxide layers 38 embedded in the vibrator 30, and
(TCf₁)_{Si} is the temperature coefficient of frequency of the single crystal silicon constituting the vibrator 30.

“r” in Formula 1 is expressed by the following Formula (2):

$$r = \frac{{m}_{Si}}{{m}_{{SiO}_{2}}} \frac{{f}_{Si}^{2}}{{f}_{{SiO}_{2}}^{2}} \qquad Formula ( 2 )$$

where m_{Si} is the mass of the single crystal silicon constituting the vibrator 30,
m_{SiO2} is the mass of silicon dioxide constituting the silicon oxide layers 38 embedded in the vibrator 30,
f_{Si} is the resonant frequency of the single crystal silicon constituting the vibrator 30, and
f_{SiO2} is the resonant frequency of silicon dioxide constituting the silicon oxide layers 38 embedded in the vibrator 30.

When the temperature dependency of the vibrator 30 disappears, that is, when the temperature coefficient of frequency (TCf₁) becomes 0, r is found by the following formula based on Formula (1) and Formula (2):

$$r = \frac{{m}_{Si}}{{m}_{{SiO}_{2}}} \frac{{f}_{Si}^{2}}{{f}_{{SiO}_{2}}^{2}} = - \frac{{( {TCf}_{1} )}_{{SiO}_{2}}}{{( {TCf}_{1} )}_{Si}} . \qquad Formula ( 3 )$$

Since the temperature coefficient of frequency (TCf₁) corresponds directly to the temperature coefficient of expansion (TCE),
if (TCf₁)_{SiO2} of Formula (3) is replaced by TCE of SiO₂, which is +179 (ppm/° C.), and
if (TCf₁)_{Si} of Formula (3) is replaced by TCE of Si, which is −63.82 (ppm/° C.),
then r=−(+179)/(−63.82)=2.8.

That is, based on Formula (2), by selecting the mass (m_{Si}) of the single crystal silicon constituting the vibrator 30 and the mass (m_{SiO2}) of the silicon dioxide constituting the silicon oxide layers 38 embedded in the vibrator 30 such that r=2.8, the temperature coefficient of frequency (TCf₁) of the vibrator 30 can be set to 0, that is, temperature dependency can be eliminated.

As described above, the silicon dioxide constituting the silicon oxide layers 38 embedded in the vibrator 30 is amorphous, and its temperature expansion coefficient, for example, does not depend on the crystal orientation unlike single crystal silicon, and has a positive temperature dependency in contrast to single crystal silicon. Therefore, by adjusting the mass of the silicon oxide layers 38 embedded in the vibrator 30, the temperature characteristics of both materials can be offset, making it possible to provide the MEMS device 100 in which the temperature dependency of the temperature coefficient of frequency and the like is reduced or eliminated.

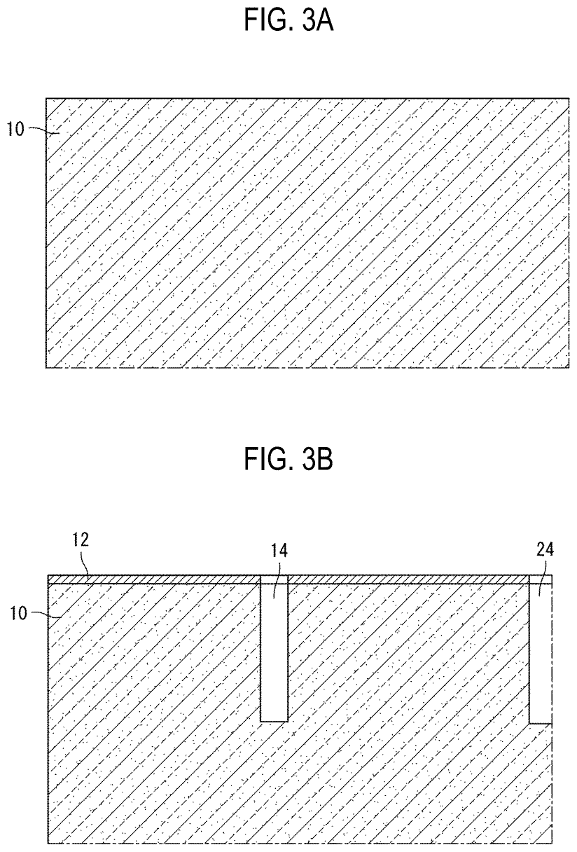

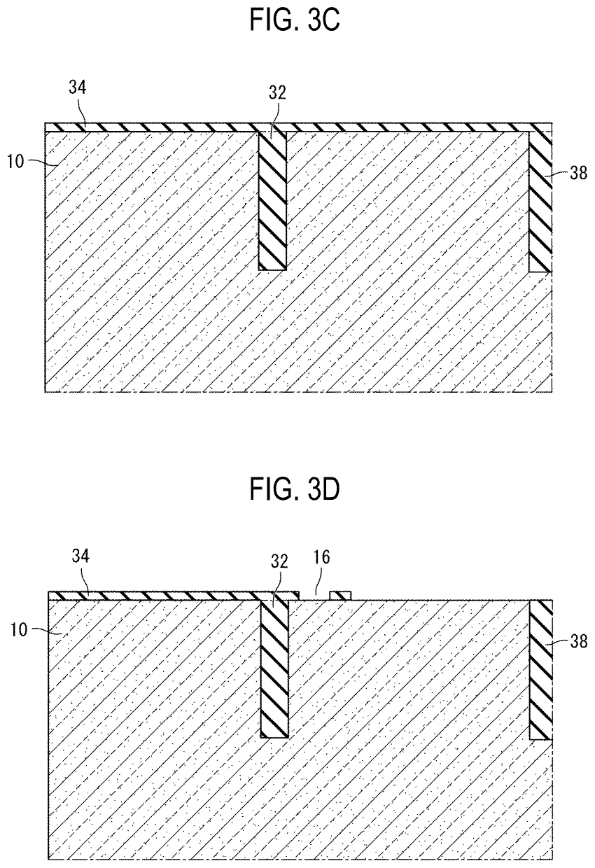

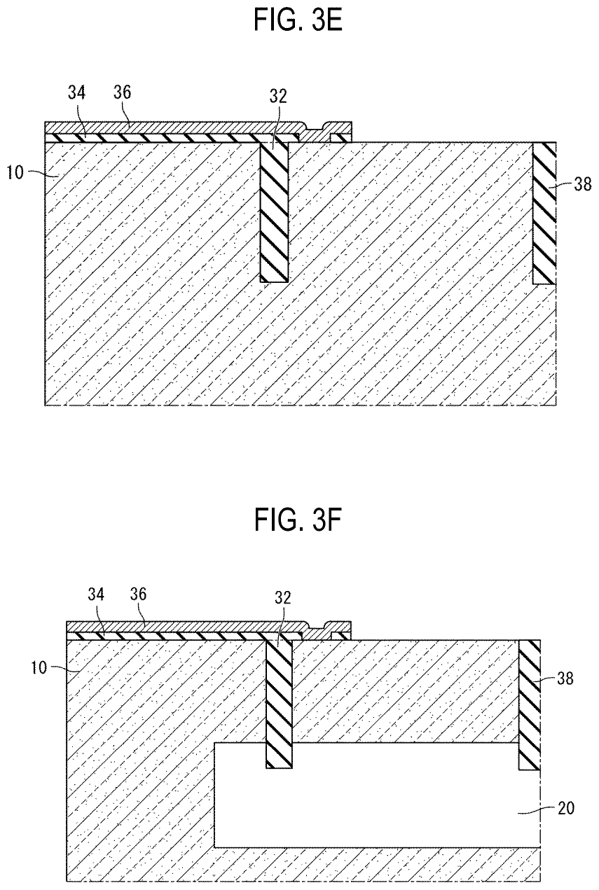

Next, with reference to FIGS. 3A to 3F, a manufacturing method of the vibrator 30 of the MEMS device 100 will be explained. FIGS. 3A to 3F illustrates a cross-section viewed from the III-III direction of FIG. 1, and in FIGS. 3A to 3F, the same reference characters as those of FIGS. 1 and 2 represent the same or corresponding parts. The manufacturing method of the vibrator 30 includes Steps 1 to 6 below.
Step 1: As illustrated in FIG. 3A, a single crystal silicon substrate 10 having a front surface and rear surface is prepared.
Step 2: As illustrated in FIG. 3B, a silicon oxide film 12 is formed by performing thermal oxidation on the front surface of the substrate 10. Next, the silicon oxide film 12 is patterned/etched to form openings, and then the substrate 10 is etched using the silicon oxide film 12 as a mask to form trenches 14 and 24.
Step 3: As illustrated in FIG. 3C, after removing the silicon oxide film 12, the front surface of the substrate 10, and the side and bottom surfaces of the trenches 14 and 24 are oxidated through thermal oxidation, for example. As a result, a silicon oxide layer is formed on the front surface of the substrate 10, and the IJ 32 and silicon oxide layer 38 are formed inside the trenches 14 and 24.
Step 4: As illustrated in FIG. 3D, the silicon oxide layer is partially etched by patterning/etching using a photoresist (not shown) to form the passivation film 34 made of silicon oxide, for example, and an opening 16.
Step 5: As illustrated in FIG. 3E, after forming an AlCu film on the front surface of the substrate 10 by sputtering, for example, the wiring layer 36 made of AlCu is formed on the passivation film 34 and in the opening 16 by patterning/etching using a photoresist (not shown).
Step 6: As illustrated in FIG. 3F, the recess 20 is formed by etching the substrate 10 from the front surface. In this way, the vibrator 30 illustrated in FIG. 2 that includes the IJ 32 and the embedded silicon oxide layer 38 and that is supported in the air above the recess 20 is completed. Because the substrate 10 around the IJ 32 is removed by etching (see FIGS. 1 and 2), the substrate 10 and the vibrator 30 are insulated by the IJ 32 made of silicon oxide.

In the MEMS device 100 of Embodiment 1, the configuration in which the bottom of the silicon oxide layer 38 protrudes from the lower end of the vibrator 30 was explained, but the silicon oxide layer 38 may be buried in the vibrator 30 without protruding therefrom.

### Embodiment 2

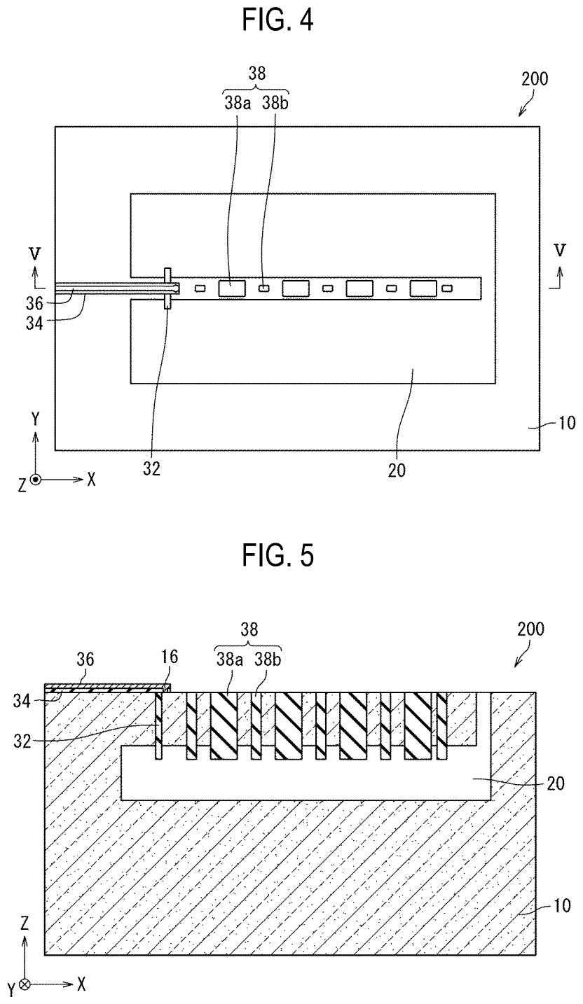

FIG. 4 is a plan view of a MEMS device according to Embodiment 2 of the present invention. The entire configuration is denoted with 200. FIG. 5 is a cross-sectional view of the MEMS device of FIG. 4 viewed from the V-V direction. In FIGS. 4 and 5, the same reference characters as those of FIGS. 1 and 2 represent the same or corresponding parts.

As illustrated in FIGS. 4 and 5, in the MEMS device 200, the silicon oxide layer 38 is constituted of two types of silicon oxide layers 38a and 38b with differing cross-sectional shapes in a plan view (see FIG. 4). The two types of silicon oxide layers 38a and 38b are arranged alternately along the longitudinal direction (x-axis direction) of the vibrator 30. The two types of silicon oxide layers 38a and 38b have the same depth. Other configurations are the same as those of the MEMS device 100 of Embodiment 1.

When the silicon oxide layer 38 is formed by internal oxidation of the trenches in the vibrator 30 made of single crystal silicon, stress is applied from silicon dioxide to silicon due to the difference in coefficient of thermal expansion (CTE) between silicon and silicon dioxide. The silicon oxide layers 38a and 38b with different sizes generate different degrees of stress affecting its surroundings.

As described above, by forming the silicon oxide layers 38a and 38b, the temperature dependency such as temperature coefficient of frequency can be reduced or eliminated. Also, by forming two types of silicon oxide layers 38a and 38b with different sizes, the stress in the vibrator 30 can be locally controlled, which makes it possible to correct or prevent unwanted deformation of the vibrator 30.

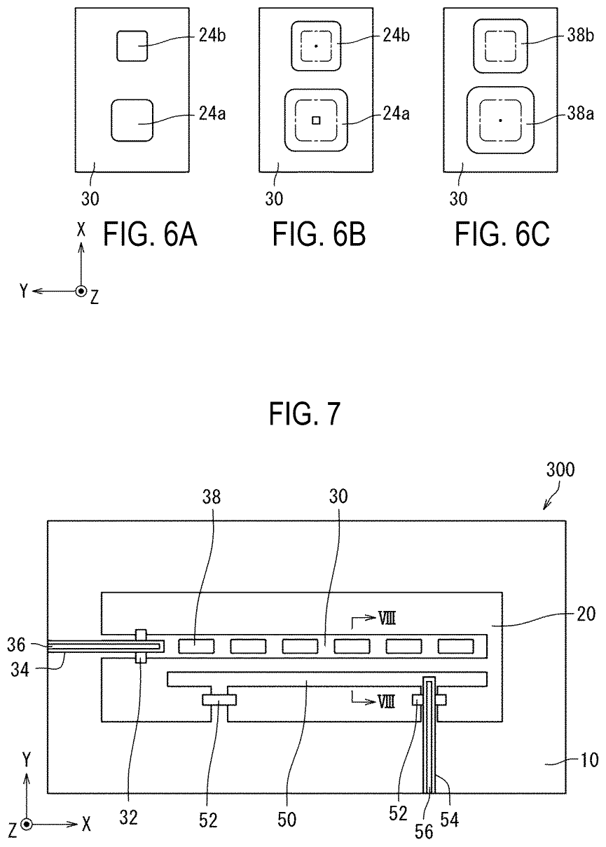

FIGS. 6A, 6B and 6C are plan views similar to FIG. 4, schematically illustrating a manufacturing process of the two types of silicon oxide layers 38a and 38b according to Embodiment 2 of the present invention.

To manufacture the silicon oxide layers 38a and 38b, in Step 2 of the manufacturing process of the MEMS device 100 of Embodiment 1 described above, trenches 24a and 24b with differing cross-sectional shapes are formed by etching the substrate 10 using as a mask the silicon oxide film 12 that is formed by performing thermal oxidation on the front surface of the substrate 10 as illustrated in FIG. 6A. Although not shown in FIGS. 6A-6C, the trench 14 for forming the IJ 32 is formed in the same manner as Embodiment 1.

Next, as illustrated in FIG. 6B, after removing the silicon oxide film 12, the side surfaces and bottom surfaces of the trenches 24a and 24b are oxidated by thermal oxidation, for example.

This way, as illustrated in FIG. 6C, the silicon oxide layers 38a and 38b can be formed. In this process, a greater stress is applied to the periphery of the silicon oxide layer 38b having a smaller cross-sectional area than to the periphery of the silicon oxide layer 38a having a larger cross-sectional area.

By forming two types of silicon oxide layers 38a and 38b having different cross-sectional areas, the stress applied to the vibrator 30 can be locally changed, which makes it possible to locally correct or prevent deformation of the vibrator 30.

Described above was the case where two types of silicon oxide layers 38a and 38b having different cross-sectional areas are alternately arranged in the longitudinal direction, but three or more different types of silicon oxide layers may be used. Also, the order of the layers is not limited to the one described above.

### Embodiment 3

FIG. 7 is a plan view of a MEMS device according to Embodiment 3 of the present invention, and the entire device is denoted with 300. In FIG. 7, the same reference characters as those of FIGS. 1 and 2 represent the same or corresponding parts.

As illustrated in FIG. 7, in the MEMS device 300, an electrode 50 is disposed only on one side of the vibrator 30. The electrode 50 is connected to the substrate 10 at two locations, and supported in the air above the recess 20. The substrate 10 and the electrode 50 are insulated from each other by an IJ 52, and a wiring layer 56 formed on a passivation film 54 connects the electrode 50 to an electrode pad (not shown). Other configurations are the same as those of the MEMS device 100 of Embodiment 1.

The MEMS device 300 is also configured such that the vibrator 30 is provided with the silicon oxide layers 38, and as a result, in the MEMS device 300 as well, the temperature dependency such as temperature coefficient of frequency and the like can be reduced or eliminated.

In the MEMS device 300 as well, the silicon oxide layers 38 may be constituted of a plurality of silicon oxide layers with differing cross-sectional shapes.

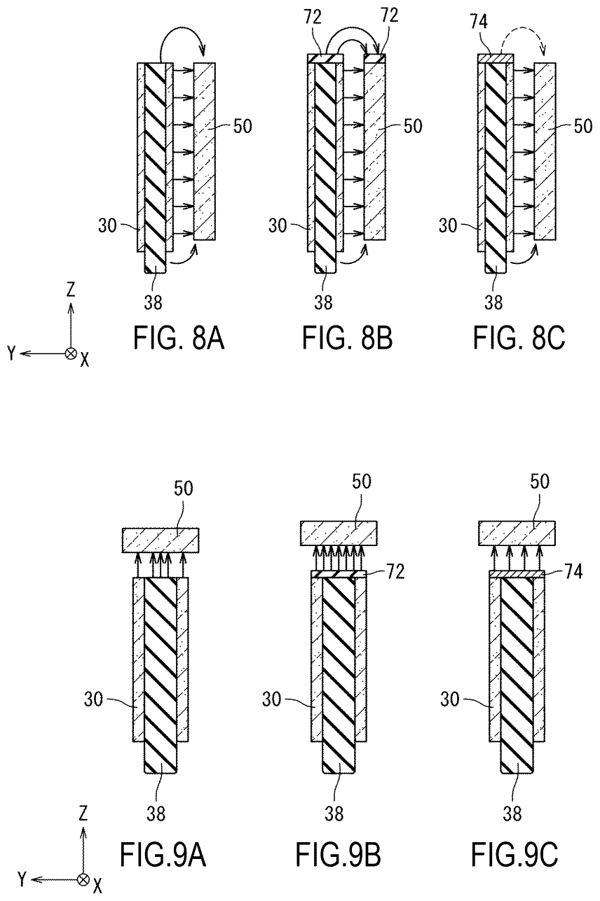

FIGS. 8A, 8B and 8C illustrate cross-sections viewed from the VII-VII direction of FIG. 7. FIG. 8A is a cross-section of the MEMS device 300 in FIG. 7. FIG. 8B illustrates a case where an insulating layer 72 such as silicon oxide is formed on the vibrator 30, and FIG. 8C illustrates a case where a conductive layer 74 such as metal or amorphous silicon is formed on the vibrator 30. The arrows indicate the direction of the electric field.

The electric field between the vibrator 30 and the electrode 50 is preferably formed in a direction perpendicular to the side surfaces of the vibrator 30 and the electrode 50 (Y-axis direction). Because the vibrator 30 and the electrodes 50, both made of single crystal silicon, are conductive, the electric field is formed in parallel with the Y-axis direction.

As described above, in the MEMS device 300 according to Embodiment 3 (as well as the MEMS devices 100 and 200), the silicon oxide layer 38 is embedded in the vibrator 30 made of conductive single crystal silicon, and the surface is covered with conductive single crystal silicon. Therefore, no charge accumulation occurs on the side surface of the vibrator 30 and there is no effect on the electric field.

On the other hand, because the silicon oxide layer 38 embedded in the vibrator 30 is an insulator, charges are accumulated on the surface thereof. Thus, as indicated by the curved arrow in FIG. 8A, curved electric fields are generated at the upper and lower ends of the vibrator 30 from the silicon oxide layer 38 toward the electrode 50. Such electric fields may adversely affect the characteristics of the vibrator 30.

As illustrated in FIG. 8B, when the upper surface of the vibrator 30 is covered by the insulating layer 72, charges are accumulated on the insulating layer 72, and the resultant electric fields (curved arrow) increases. Such electric fields may adversely affect the characteristics of the vibrator 30.

On the other hand, as illustrated in FIG. 8C, when the upper surface of the vibrator 30 is covered by the conductive layer 74 such as amorphous silicon or metal, no charges are accumulated on the silicon oxide layer 38, and therefore, electric fields caused by the accumulated charges (dashed curved arrow) can be reduced or eliminated.

FIGS. 9A, 9B and 9C illustrate electric fields when the electrode 50 is disposed above the vibrator 30 (z-axis direction), unlike the structure of FIGS. 8A-8C. In FIGS. 9A-9C, the same reference characters as those of FIGS. 8A-8C represent the same or corresponding parts.

As illustrated in FIG. 9A, when the surface of the vibrator 30 is exposed, the silicon oxide layer 38 may affect the electric field.

As illustrated in FIG. 9B, when the upper surface of the vibrator 30 is covered by the insulating layer 72, electric field becomes stronger, but charges accumulated on the insulating layer 72 affect the behavior of the electric field.

On the other hand, as illustrated in FIG. 9C, when the upper surface of the vibrator 30 is covered by the conductive layer 74, no charges are accumulated on the silicon oxide layer 38, which reduces or eliminates electric fields caused by the accumulated charges.

In FIGS. 8A-8C and 9A-9C, the effect of charge accumulation increases in the following order from smallest to largest: (8C) the configuration in which the silicon oxide layer 38 is covered by the conductive layer 74; (8A) the configuration in which the silicon oxide layer 38 is exposed; and (8B) the configuration in which the silicon oxide layer 38 is covered by the insulating layer 72. Therefore, to prevent the effect of the accumulated charges, the configuration of 8C is most preferable, followed by the configuration of 8B.

In Embodiments 1 to 3 above, a resonator was explained as an example, but in other types of MEMS devices such as acceleration sensors, it is possible to prevent or reduce changes in the characteristics of the MEMS device caused by changes in temperature by providing the silicon oxide layer 38 in a movable electrode (e.g., the vibrator 30) made of single crystal silicon, and further by forming silicon oxide layers 38a and 38b having different cross-sectional areas. Furthermore, by providing a conductive layer on the silicon oxide layer 38, the effect of the accumulated charges on the electric field can also be prevented or reduced.

### (Supplementary Notes)

The present disclosure is a MEMS device including:
a substrate having a front surface and a rear surface;
a recess formed on the front surface of the substrate; and
a movable electrode and a fixed electrode connected to the substrate and disposed in such a manner as to face each other in the air above the recess,
wherein the movable electrode includes an embedded oxide layer embedded in a trench formed in the movable electrode.

In the MEMS device of the present disclosure, the temperature-dependent deformation of the vibrator, which has a significant effect on the device characteristics, is offset by forming the silicon oxide layers 38 having a temperature dependency (e.g., Young's modulus) opposite to that of silicon, rather than by adding a dopant. This makes it possible to prevent or reduce temperature-dependent changes in the characteristics of the MEMS device.

In the present disclosure, the movable electrode is formed of silicon, and the embedded oxide layer is formed of silicon dioxide, and the mass of the silicon and the mass of the silicon dioxide are adjusted such that, in the following formula, Tcf₁ becomes 0:

$${TCf}_{1} = \frac{{( {TCf}_{1} )}_{{SiO}_{2}} + {r ( {TCf}_{1} )}_{Si}}{1 + r}$$

where (TCf₁)_{SiO2} is the frequency temperature coefficient of silicon dioxide,
(TCf₁)_{Si} is the frequency temperature coefficient of silicon,

$$r = \frac{{m}_{Si}}{{m}_{{SiO}_{2}}} \frac{{f}_{Si}^{2}}{{f}_{{SiO}_{2}}^{2}}$$

where m_{Si} is the mass of silicon,
m_{SiO2} is the mass of silicon dioxide,
f_{Si} is the resonant frequency of silicon, and
f_{SiO2} is the resonant frequency of silicon dioxide.

This way, by forming an embedded oxide layer in the vibrator and adjusting the mass ratio of silicon and silicon dioxide that compose the vibrator, it is possible to provide a MEMS device in which the characteristics thereof do not change depending on temperature.

In the present disclosure, the embedded oxide layer may be a plurality of embedded oxide layers arranged along a longitudinal direction of the movable electrode. By forming a plurality of embedded oxide layers in the longitudinal direction, it is possible to prevent temperature-dependent deformation over the entire movable electrode.

In the present disclosure, the plurality of embedded oxide layers may be configured such that respective cross sections thereof in parallel to the front surface of the substrate differ from each other. This makes it possible to locally change the stress applied to the movable electrode, which helps to locally correct or prevent deformation of the movable electrode.

In the present disclosure, the embedded oxide layer may be configured such that it is surrounded by the movable electrode on side surfaces and bottom surface, or such that it is surrounded by the movable electrode on side surfaces, and the bottom surface thereof protrudes from the movable electrode. The embedded oxide layer may be in a trench shape with the bottom surface buried in the movable electrode, or in an isolation joint shape with the bottom surface protruding from the movable electrode.

In the present disclosure, the top surface of the embedded oxide layer is preferably covered by a conductive layer. This prevents charge accumulation on the embedded oxide layer and provides a uniform electric field.

In the present disclosure, the substrate and the movable electrode may be insulated from each other by an insulating layer (IJ) disposed therebetween. This can be applied to the SCREAM process using an insulating layer (IJ).

In the present disclosure, the movable electrode is a vibrator of a resonator, for example. This makes it possible to prevent characteristics such as the resonant frequency from varying with temperature, and therefore, an accurate resonator is achieved.

The present disclosure is a manufacturing method of a MEMS device including an embedded oxide layer embedded in a trench formed in a movable electrode, comprising:
preparing a substrate having a front surface and a rear surface;
forming a trench by etching the substrate from the front surface;
forming the embedded oxide layer in the trench by oxidating side surfaces and bottom surface of the trench; and
forming a recess by etching the substrate from the front surface to form a movable electrode supported in the air above the recess.

The embedded oxide layer can be embedded in the trench formed in the movable electrode using a common manufacturing process.

In the present disclosure, the embedded oxide layer may be configured such that it is surrounded by the movable electrode on side surfaces and bottom surface, or such that it is surrounded by the movable electrode on side surfaces and the bottom surface thereof protrudes from the movable electrode. The method of the present disclosure can be applied to both the production of an embedded oxide layer in the form of a trench and the formation of an embedded oxide layer in the form of an isolation joint.

### INDUSTRIAL APPLICABILITY

The MEMS device structure of the present invention can be applied to MEMS devices such as resonators and acceleration sensors.

What is claimed is:

1. A MEMS (Micro-Electro-Mechanical System) device, comprising:
a substrate having a front surface and a rear surface;
a recess formed on a front surface of the substrate; and
a movable electrode and a fixed electrode connected to the substrate and disposed in such a manner as to face each other above the recess,
wherein the movable electrode includes an embedded oxide layer embedded in a trench formed in the movable electrode.

2. The MEMS device according to claim 1,
wherein the movable electrode is formed of silicon, and the embedded oxide layer is formed of silicon dioxide, and a mass of silicon and a mass of silicon dioxide are adjusted such that, in the following formula, Tcf₁ becomes 0:
$${TCf}_{1} = \frac{{( {TCf}_{1} )}_{{SiO}_{2}} + {r ( {TCf}_{1} )}_{Si}}{1 + r}$$
where (TCf₁)_{SiO2} is a frequency temperature coefficient of silicon dioxide,
(TCf₁)_{Si} is a frequency temperature coefficient of silicon,
$$r = \frac{{m}_{Si}}{{m}_{{SiO}_{2}}} \frac{{f}_{Si}^{2}}{{f}_{{SiO}_{2}}^{2}}$$
where m_{Si} is the mass of silicon,
m_{SiO2} is the mass of silicon dioxide,
f_{Si} is a resonant frequency of silicon, and
f_{SiO2} is a resonant frequency of silicon dioxide.

3. The MEMS device according to claim 1, wherein the embedded oxide layer is a plurality of embedded oxide layers arranged along a longitudinal direction of the movable electrode.

4. The MEMS device according to claim 3, wherein the plurality of embedded oxide layers are configured such that respective cross sections of the plurality of embedded oxide layers in parallel with the front surface of the substrate differ from each other.

5. The MEMS device according to claim 1, wherein the embedded oxide layer is configured such that the embedded oxide layer is surrounded by the movable electrode on side surfaces and a bottom surface of the embedded oxide layer, or such that the embedded oxide layer is surrounded by the movable electrode on the side surfaces and the bottom surface the embedded oxide layer protrudes from the movable electrode.

6. The MEMS device according to claim 1, wherein a top surface of the embedded oxide layer is covered by a conductive layer.

7. The MEMS device according to claim 1, wherein the substrate and the movable electrode are insulated from each other by an insulating layer disposed therebetween.

8. The MEMS device according to claim 1, wherein the movable electrode is a vibrator of a resonator.

9. A manufacturing method of a MEMS device including an embedded oxide layer embedded in a trench formed in a movable electrode, comprising:
preparing a substrate having a front surface and a rear surface;
forming a trench by etching the substrate from the front surface;
forming the embedded oxide layer in the trench by oxidating side surfaces and a bottom surface of the trench; and
forming a recess by etching the substrate from the front surface to form a movable electrode supported above the recess.

10. The manufacturing method according to claim 9,
wherein the embedded oxide layer is configured such that the embedded oxide layer is surrounded by the movable electrode on side surfaces and a bottom surface of the embedded oxide layer, or such that the embedded oxide layer is surrounded by the movable electrode on the side surfaces and the bottom surface the embedded oxide layer protrudes from the movable electrode.
